(19) United States
(12) Patent Application Publication
(10) Pub. No.: US 2026/0211048 A1
(43) Pub. Date: Jul. 23, 2026

(54) FULL CHARGE CAPACITY CALCULATING DEVICE AND FULL CHARGE CAPACITY CALCULATING METHOD

(71) Applicant: TOYOTA JIDOSHA KABUSHIKI KAISHA, Toyota-shi Aichi-ken (JP)

(72) Inventor: Takuro SHIMIZU, Nisshin-shi Aichi-ken (JP)

(73) Assignee: TOYOTA JIDOSHA KABUSHIKI KAISHA, Toyota-shi Aichi-ken (JP)

(21) Appl. No.: 19/389,277

(22) Filed: Nov. 14, 2025

(30) Foreign Application Priority Data
Nov. 18, 2024 (JP) 2024-200857

(51) Int. Cl. G01R 31/388; G01R 31/396

(52) U.S. Cl. CPC G01R 31/388; G01R 31/396

(57) ABSTRACT

A full charge capacity calculating device configured to calculate the full charge capacity of a battery includes: a setting unit configured to set, based on the electric current and the temperature of the battery, a control lower limit at which the deviation between the open circuit voltage and the closed circuit voltage of the battery is corrected; a measuring unit configured to charge the battery in a predetermined section and measure the integrated value of electric current in the section when the state of the battery reaches the control lower limit; and a calculating unit configured to calculate the full charge capacity of the battery based on the stored energy of the battery when the control lower limit is reached and the integrated value of electric current.

### CROSS-REFERENCE TO RELATED APPLICATION

This application claims priority to Japanese Patent Application No. 2024-200857 filed on Nov. 18, 2024. The disclosure of the above-identified application, including the specification, drawings, and claims, is incorporated by reference herein in its entirety.

### BACKGROUND

### 1. Technical Field

The present disclosure relates to a device and a method that each calculate the full charge capacity of a battery that is mounted on a vehicle or the like.

### 2. Description of Related Art

Japanese Unexamined Patent Application Publication No. 2008-261669 (JP 2008-261669 A) discloses a technology capable of accurately calculating the full charge capacity of a battery without completely discharging the battery or fully charging the battery. The technology calculates the full charge capacity of the battery based on a capacity change value of the battery and the rate of change in the state of charge (SOC), in charging processing from a lower limit open circuit voltage (OCV) to an upper limit open circuit voltage.

### SUMMARY

JP 2008-261669 A is a technology that calculates the full charge capacity of the battery based on the open circuit voltage fluctuating along with the change in the state of charge of the battery and it is necessary to obtain the open circuit voltage of the battery. An onboard battery or the like included in a closed circuit constantly connected to an electrical load is, however, capable of obtaining a closed circuit voltage (CCV), but incapable of obtaining the open circuit voltage. The values of voltages obtained for an open circuit and a closed circuit have a deviation, raising a problem that it is not possible to apply the technology according to JP 2008-261669 A to the battery included in the closed circuit or calculate the full charge capacity.

The present disclosure provides a full charge capacity calculating device and a full charge capacity calculating method for a battery, that each make it possible to calculate the full charge capacity even for a battery for which it is not possible to obtain the open circuit voltage.

A full charge capacity calculating device according to a first aspect of the present disclosure is configured to calculate the full charge capacity of a battery. The full charge capacity calculating device includes: a setting unit configured to set, based on the electric current and the temperature of the battery, a control lower limit at which the deviation between the open circuit voltage and the closed circuit voltage of the battery is corrected; a measuring unit configured to charge the battery in a predetermined section and measure the integrated value of electric current in the section when the state of the battery reaches the control lower limit; and a calculating unit configured to calculate the full charge capacity of the battery based on the stored energy of the battery when the control lower limit is reached and the integrated value of electric current.

In the full charge capacity calculating device according to the first aspect of the present disclosure, the battery may be a lithium-ion battery having an SOC-OCV characteristic having a flat region in which the rate of change in the open circuit voltage to the stored energy is a predetermined value or less. The setting unit may set the control lower limit in a region having the stored energy that is lower than the stored energy of the flat region.

In the full charge capacity calculating device according to the first aspect of the present disclosure, the setting unit may set the control lower limit when the electric current of the battery is predetermined electric current or less and the temperature of the battery is predetermined temperature or more.

A full charge capacity calculating method of calculating the full charge capacity of a battery according to a second aspect of the present disclosure includes: setting, based on the electric current and the temperature of the battery, a control lower limit at which the deviation between the open circuit voltage and the closed circuit voltage of the battery is corrected; charging the battery in a predetermined section and measuring the integrated value of electric current in the section when the state of the battery reaches the control lower limit; and calculating the full charge capacity of the battery based on the stored energy of the battery when the control lower limit is reached and the integrated value of electric current.

A full charge capacity calculating device according to a third aspect of the present disclosure is configured to calculate the full charge capacity of a battery. The full charge capacity calculating device includes a processor. The processor is configured to set, based on the electric current and the temperature of the battery, a control lower limit at which the deviation between the open circuit voltage and the closed circuit voltage of the battery is corrected. The processor is configured to charge the battery in a predetermined section and measure the integrated value of electric current in the section when the state of the battery reaches the control lower limit. The processor is configured to calculate the full charge capacity of the battery based on the stored energy of the battery when the control lower limit is reached and the integrated value of electric current.

The full charge capacity calculating device and the full charge capacity calculating method according to the present disclosure each execute processing of measuring the integrated value of electric current using the control lower limit at which the deviation between the open circuit voltage and the closed circuit voltage of the battery is corrected. It is thus possible to accurately calculate, from the closed circuit voltage, the full charge capacity even for a battery for which it is not possible to obtain the open circuit voltage.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a full charge capacity calculating device for a battery according to an embodiment of the present disclosure;

FIG. 2 is a processing flowchart describing a full charge capacity calculating method for the battery according to the embodiment of the present disclosure;

FIG. 3 is a diagram illustrating an example of an SOC-OCV characteristic curve having a flat region; and

FIG. 4 is an example of a two-dimensional map used to set a control lower limit voltage.

### DETAILED DESCRIPTION OF EMBODIMENTS

A full charge capacity calculating device and a full charge capacity calculating method for a battery according to the present disclosure each absorb the deviation between an open circuit voltage (OCV) and a closed circuit voltage (CCV) by correcting the values of the voltages at a control lower limit in a state in which the battery has sufficiently small dark current and high battery temperature.

Hereinafter, an embodiment of the present disclosure will be described in detail with reference to the drawings.

### Embodiment

### Configuration

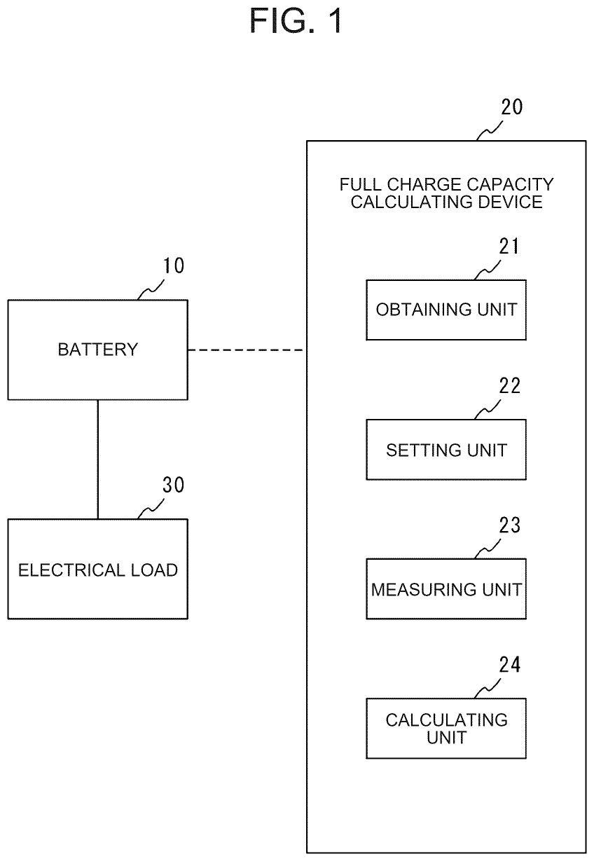

FIG. 1 is a functional block diagram illustrating the schematic configuration of a full charge capacity calculating device 20 for a battery 10 according to an embodiment of the present disclosure. The full charge capacity calculating device 20 exemplified in FIG. 1 includes an obtaining unit 21, a setting unit 22, a measuring unit 23, and a calculating unit 24. For example, the full charge capacity calculating device 20 calculates (estimates) the full charge capacity of the battery 10. The battery 10 and the full charge capacity calculating device 20 are mounted, for example, on a vehicle.

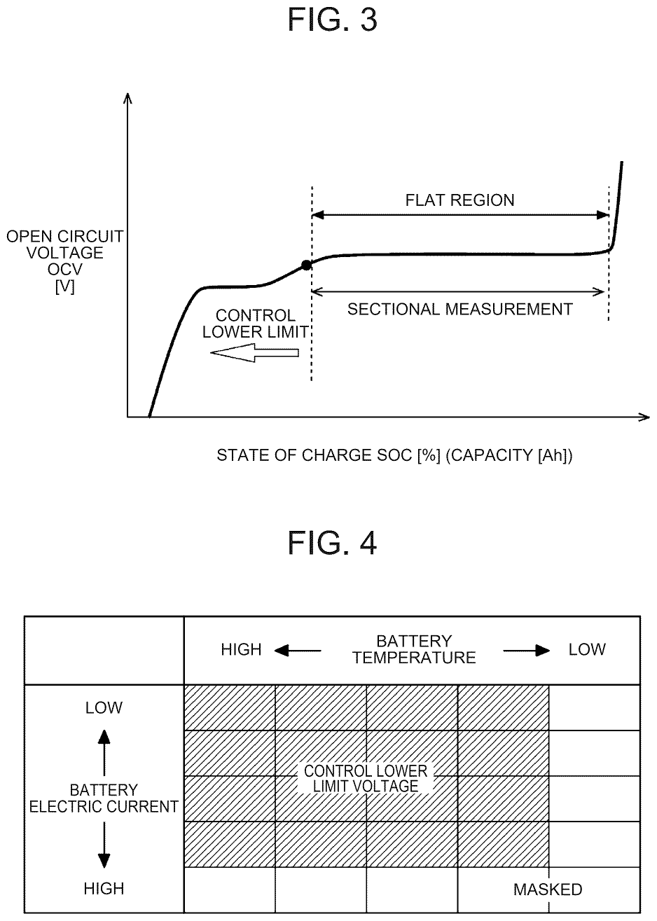

The battery 10 is a secondary battery configured to be chargeable and dischargeable to supply electric power to an electrical load 30, such as a device and an apparatus. Normally, the battery 10 is constantly connected to the electrical load 30 electrically. A lithium-ion battery (such as an LFP battery) having SOC-OCV characteristics having a flat region in which the rate of change in the open circuit voltage (OCV) to the stored energy (or SOC) as illustrated in FIG. 3 is a predetermined value or less is used for the battery 10. Examples of the battery 10 that is mounted on the vehicle include an auxiliary battery that supplies electric power to the auxiliary electrical load 30.

The obtaining unit 21 is a component that obtains the state of the battery 10, such as the voltage (closed circuit voltage), the electric current (inflow-outflow electric current), the temperature, and the stored energy of the battery 10. The obtaining unit 21 is capable of obtaining the state of the battery 10 from various detection sensors (not illustrated) provided to the battery 10.

The setting unit 22 is a component that sets a control lower limit of the battery 10. The control lower limit is set as the value of a region having a lower stored energy than the stored energy of the flat region of the SOC-OCV characteristics of the battery 10 that is a lithium-ion battery. Specifically, the control lower limit is provided as the value of a voltage (referred to as “control lower limit voltage” below) at which the deviation (voltage difference) between the open circuit voltage (OCV) and the closed circuit voltage (CCV) is corrected (see FIG. 3). An appropriate value is set in advance for the control lower limit voltage depending on various combinations of the electric current of the battery 10 and the temperature of the battery 10. The control lower limit voltage is provided, for example, by a two-dimensional map illustrated in FIG. 4. The target electric current of the battery 10 in the present embodiment is specifically electric current (dark current) flowing from the battery 10 to the electrical load 30 in a state (e.g., the state of the vehicle such as IG-OFF or Ready-OFF) in which an electric power supply system is stopped.

The measuring unit 23 is a component that charges the battery 10 in a predetermined section and measures (sectional measurement) the integrated value of electric current in the section when the state of the battery 10 reaches the control lower limit (voltage). FIG. 3 illustrates an image of a section in which the measuring unit 23 performs an integration of electric current. It is possible to use various well-known techniques to measure the integrated value of electric current.

The calculating unit 24 is a component that calculates (estimates) the full charge capacity of the battery 10. The full charge capacity is calculated based on the stored energy of the battery 10 when the state of the battery 10 reaches the control lower limit (voltage) set by the setting unit 22 and the integrated value of electric current obtained by the measuring unit 23 performing sectional measurement.

Part or the whole of the full charge capacity calculating device 20 described above may be typically configured as an electronic control unit (ECU) including a processor, a memory, an input-output interface, and the like. The electronic control unit achieves functions of all or some of the obtaining unit 21, the setting unit 22, the measuring unit 23, and the calculating unit 24 by the processor reading and executing a program stored in the memory.

### Control

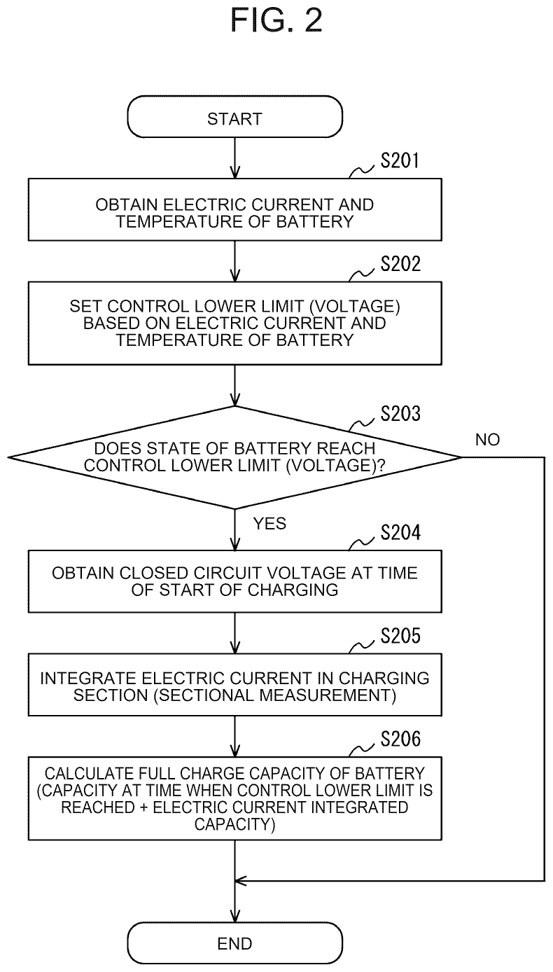

Next, the full charge capacity calculating method that is executed by the full charge capacity calculating device 20 according to the embodiment of the present disclosure will be described with reference to further FIG. 2. FIG. 2 is a flowchart illustrating a processing procedure of full charge capacity calculating control over the battery 10 that is executed by the respective components of the full charge capacity calculating device 20. The full charge capacity calculating control exemplified in FIG. 2 is started, for example, by sensing a stop of the electric power supply system including the battery 10 as a component or receiving a predetermined request.

### Step S201

The obtaining unit 21 of the full charge capacity calculating device 20 obtains the electric current (or the dark current) and the temperature of the battery 10 as the state of the battery 10. To obtain the electric current and the temperature, an electric current sensor, a temperature sensor, and the like (not illustrated) are used.

When the obtaining unit 21 obtains the electric current and the temperature of the battery 10, the processing advances to step S202.

### Step S202

The setting unit 22 of the full charge capacity calculating device 20 sets the control lower limit (voltage) of the battery 10 based on the electric current and the temperature of the battery 10. It is possible to determine the set control lower limit (voltage), for example, by looking up in a map using the two-dimensional map exemplified in FIG. 4 (shaded regions of FIG. 4). It is to be noted that the battery 10 has a greater deviation between the open circuit voltage (OCV) and the closed circuit voltage (CCV) and it is not possible to expect the correction to be accurate in the present embodiment when the battery 10 has too high electric current or when the battery 10 has too low temperature. The control lower limit (voltage) is not thus set (unshaded regions in FIG. 4) such that the full charge capacity calculating control over the battery 10 is not executed (is masked).

When the setting unit 22 sets the control lower limit (voltage) of the battery 10, the processing advances to step S203.

### Step S203

The measuring unit 23 of the full charge capacity calculating device 20 determines whether or not the state of the battery 10 reaches the control lower limit (voltage). Examples of the state of the battery 10 include a voltage and the stored energy (SOC). In the case of a voltage, the voltage is compared with the control lower limit (voltage) to make the determination. In the case of the stored energy, the open circuit voltage (OCV) derived from the SOC-OCV characteristic curve is compared with the control lower limit (voltage) to make the determination.

When the measuring unit 23 determines that the state of the battery 10 reaches the control lower limit (voltage) (Yes in step S203), the processing advances to step S204. In contrast, when the measuring unit 23 determines that the state of the battery 10 does not reach the control lower limit (voltage) (No in step S203), the full charge capacity calculating control over the present battery 10 comes to an end.

### Step S204

The obtaining unit 21 of the full charge capacity calculating device 20 obtains the closed circuit voltage (CCV) of the battery 10 as the state of the battery 10. The closed circuit voltage serves as a charge start voltage of sectional measurement processing executed by the measuring unit 23 in step S205 described below.

When the obtaining unit 21 obtains the closed circuit voltage of the battery 10, the processing advances to step S205.

### Step S205

The measuring unit 23 of the full charge capacity calculating device 20 executes sectional measurement processing of charging (or charging and discharging) the battery 10 in a predetermined section and measuring the integrated value of electric current in the section (charging section) of the charging. The predetermined section may be, for example, any section from a region below the control lower limit of the battery 10 to a region in which the flat region of the SOC-OCV characteristics is exceeded and the stored energy (or SOC) is high. The measured integrated value of electric current is recorded in a predetermined memory or the like (not illustrated).

When the measuring unit 23 executes the sectional measurement processing of measuring the integrated value of electric current in the charging section, the processing advances to step S206.

### Step S206

The calculating unit 24 of the full charge capacity calculating device 20 calculates the full charge capacity of the battery 10. The full charge capacity is calculated in accordance with the following (Expression 1) from the stored energy (capacity at the time when the control lower limit is reached) of the battery 10 when the state of the battery 10 reaches the control lower limit (voltage) in step S203 and capacity (electric current integrated capacity) based on the integrated value of electric current obtained through the sectional measurement in step S205.

$$full charge capacity = capacity at time when control lower limit is reached + electric current integrated capacity \qquad ( Expression 1 )$$

When the full charge capacity of the battery 10 is calculated, the full charge capacity calculating control over the present battery 10 comes to an end.

### Workings and Effects

As described above, the full charge capacity calculating device 20 and the full charge capacity calculating method for the battery 10 according to the embodiment of the present disclosure each set the control lower limit at which the deviation between the open circuit voltage (OCV) and the closed circuit voltage (CCV) of the battery 10 is corrected based on the electric current of the battery 10 and the temperature of the battery 10, charge the battery 10 in a predetermined section defined using the closed circuit voltage and measure the integrated value of electric current in the section when the state of the battery 10 reaches the control lower limit, and calculate the full charge capacity of the battery 10 from the stored energy of the battery 10 when the control lower limit is reached and the capacity based on the integrated value of electric current.

As described above, in the case of even the battery 10 for which it is not possible to obtain the open circuit voltage, it is possible to accurately calculate (estimate) the full charge capacity of the battery 10 by using a control technique that narrows down scenes by the conditions of the electric current and the temperature of the battery 10 and corrects the deviation between the open circuit voltage and the closed circuit voltage in consideration of the SOC-OCV characteristic curve (battery data) of the battery 10. In addition, it is possible to sense the deterioration of the battery 10 by accurately calculating the full charge capacity of the battery 10 and prevent the merchantability from decreasing.

The embodiment of the present disclosure has been described so far, but the present disclosure is not limited to the full charge capacity calculating device and the full charge capacity calculating method for the battery described above. It is possible to grasp the present disclosure as a program of the full charge capacity calculating method, a computer-readable non-transitory recording medium that stores the program, a vehicle on which the full charge capacity calculating device is mounted, or the like.

The full charge capacity calculating device and the full charge capacity calculating method for the battery according to the present disclosure are usable, for example, when where it is desirable to accurately estimate the full charge capacity of the battery.

What is claimed is:

1. A full charge capacity calculating device configured to calculate full charge capacity of a battery, the full charge capacity calculating device comprising:
a setting unit configured to set, based on electric current and temperature of the battery, a control lower limit at which a deviation between an open circuit voltage and a closed circuit voltage of the battery is corrected;
a measuring unit configured to charge the battery in a predetermined section and measure an integrated value of electric current in the section when a state of the battery reaches the control lower limit; and
a calculating unit configured to calculate the full charge capacity of the battery based on a stored energy of the battery when the control lower limit is reached and the integrated value of electric current.

2. The full charge capacity calculating device according to claim 1, wherein:
the battery is a lithium-ion battery having an SOC-OCV characteristic having a flat region in which a rate of change in the open circuit voltage to the stored energy is a predetermined value or less; and
the setting unit sets the control lower limit in a region having the stored energy that is lower than the stored energy of the flat region.

3. The full charge capacity calculating device according to claim 1, wherein the setting unit sets the control lower limit when the electric current of the battery is predetermined electric current or less and the temperature of the battery is predetermined temperature or more.

4. A full charge capacity calculating method of calculating full charge capacity of a battery, the full charge capacity calculating method comprising:
setting, based on electric current and temperature of the battery, a control lower limit at which a deviation between an open circuit voltage and a closed circuit voltage of the battery is corrected;
charging the battery in a predetermined section and measuring an integrated value of electric current in the section, when a state of the battery reaches the control lower limit; and
calculating the full charge capacity of the battery based on a stored energy of the battery when the control lower limit is reached and the integrated value of electric current.

5. A full charge capacity calculating device configured to calculate full charge capacity of a battery, the full charge capacity calculating device comprising a processor configured to
set, based on electric current and temperature of the battery, a control lower limit at which a deviation between an open circuit voltage and a closed circuit voltage of the battery is corrected;
charge the battery in a predetermined section and measure an integrated value of electric current in the section, when a state of the battery reaches the control lower limit; and
calculate the full charge capacity of the battery based on a stored energy of the battery when the control lower limit is reached and the integrated value of electric current.
